(19) United States
(12) Patent Application Publication
(10) Pub. No.: US 2015/0021442 A1
(43) Pub. Date: Jan. 22, 2015

(54) SOLAR RELAY AIRCRAFT POWERED BY GROUND BASED SOLAR CONCENTRATOR MIRRORS IN DUAL USE WITH POWER TOWERS

(71) Applicant: John William Hunter, Escondido, CA (US)

(72) Inventor: John William Hunter, Escondido, CA (US)

(21) Appl. No.: 14/014,261

(22) Filed: Aug. 29, 2013

Related U.S. Application Data
(60) Provisional application No. 61/743,227, filed on Aug. 29, 2012.
(60) Provisional application No. 61/859,728, filed on Jul. 29, 2013.

(51) Int. Cl. B64D 27/24; B64C 1/00; H01L 31/052; B64D 33/08; B64F 1/00; B64C 39/02; B64C 39/10

(52) U.S. Cl. CPC B64D 27/24; B64C 39/02; B64C 1/0009; B64C 39/10; B64D 33/08; B64F 1/00; H01L 31/0525; B64C 2039/105; B64D 2211/00
USPC 244/53 R

(57) ABSTRACT

A solar relay aircraft system includes a solar relay aircraft having an upper surface, and a lower surface, and equipped with a solar radiation receiver on said lower surface and capable of converting solar energy to electrical energy. An electric motor in electrical connection with said solar radiation receiver to receive the electrical energy and drives a propeller to propel the solar relay aircraft. A number of ground-based reflector arrays include a plurality of reflecting mirrors for receiving solar radiation from the sun and direct the solar radiation from the sun towards the solar relay aircraft.

### RELATED APPLICATIONS

This application claims the benefit of priority to U.S. Provisional Patent Application Ser. No. 61/743,227, filed Aug. 29, 2012 entitled “Solar Relay Aircraft Powered By Ground Based Solar Concentrator Mirrors In Dual Use with Power Towers”, and U.S. Provisional Patent Application Ser. No. 61/859,728, filed Jul. 29, 2013 entitled Solar Relay Aircraft Powered By Ground Based Mirros in Dual Use with Power Towers”; both applications currently co-pending.

### FIELD OF THE INVENTION

This invention relates generally to the direction and use of solar energy power. This invention is more particularly, though not exclusively, useful as a solar collector system for providing energy to solar powered aircraft and for

### BACKGROUND OF THE INVENTION

With over 87000 flights per day, airplanes have become a major mode of transportation for goods and people. Despite the utility of the modern day airplanes, these airplanes have their limitations. Conventional airplanes are powered with combustible fuels which are heavy, expensive, polluting, and are used-up quickly. The weight of the airplane with the additional weight of the fuel is heavy and thus requires a substantial amount of energy to operate.

This limits the payload as well the operating time of an aircraft. Additionally, the large amounts of fuel used create excessive pollutants. Given the rising cost of fuel, conventional airplanes operate with large expenses per flight hour. As a result, solar/electric powered aircrafts have been introduced to address the limitations of combustible fuel airplanes.

Using solar energy solves some of the major limitations of conventional combustible fueled aircrafts. Solar energy is unlimited, is readily available during daylight hours, does not need to be stored, does not add any weight, has a zero net effect on the environment, and is free and therefore not susceptible to price fluctuations. Working models have demonstrated the feasibility and utility of solar powered aircrafts. However, current solar powered aircrafts do not provide the same utility as combustible fueled aircrafts. One primary reason for this deficiency is that current solar powered aircrafts receive their energy directly from the sun through upper surface mounted solar cells, and thus operate at a single-sun solar power level. Many solar powered aircrafts rely on photovoltaic cells to convert solar energy into electricity to power an electric motor based propulsion system. A problem associated with using photovoltaic solar cells for aircrafts is the need to orient and position the photovoltaic solar cells to the sun to achieve maximum efficiency. Wing-mounted arrays of solar panels limit the efficiency of the collection of solar power as the wings are stationary and do not adapt to the moving sun throughout the day. Additionally, weather patterns affect the amount of solar energy available to photovoltaic cells. As a result, batteries or other types of energy storage systems are installed onboard the aircraft to store electrical energy and keep the aircraft aloft in circumstances where the photovoltaic cells may not provide enough electricity.

However, energy storage systems such as the battery impose a substantial weight burden on the aircraft. Furthermore, current photovoltaic/electric propulsion systems have a relatively small power to weight ratio, limiting the total weight a solar/electric aircraft can be. The tactic of adding additional surface area in which to mount photovoltaic cells beyond the minimum needed for the aircraft to fly or to add additional batteries rapidly reaches a point of diminishing returns. This is because the additional surface area results in additional weight and drag that require more energy to fly than the additional solar energy collected by the added surface area. Likewise, the energy required to lift the additional weight of the batteries is more energy than the battery may provide.

In light of the above, it would be advantageous to provide an aircraft powered by solar energy with the ability to produce higher thrust than conventional solar powered aircrafts to enable it to move at higher speeds and carry higher payloads. As a solar powered aircraft, it would operate with minimal noise and pollutants. It would further be advantageous to provide a solar powered aircraft having a high enough lift to drag ratio to reduce the power requirements of the aircraft. It would further be advantageous to provide a solar powered aircraft utilizing high efficiency motors to maximize the amount of available power. It would further be advantageous to provide a solar powered aircraft with the ability to intercept and receive solar rays at angles between 10 to 90 degrees, minimizing the need to directly face the sun. It would also be advantageous to provide a means capable of delivering concentrated solar power, such as solar power at multiple-sun intensities, to an aircraft at various angles flying along a path and to alternatively deliver concentrated solar power to stationary solar panels to energize the grid when not directed towards solar aircrafts. It would further be advantageous to provide a means of delivering concentrated solar energy that is cheap to construct and cost-effective.

### SUMMARY OF THE INVENTION

The present invention includes a transportation system having a solar powered aircraft, a means of using concentrated solar power directed from ground based mirrors to power aircraft at useful speeds along a path, and a control system to direct a reflected solar power beam toward passing solar powered aircraft and alternatively, to a solar energy collector, such as photovoltaic or steam generation. This system allows for the solar powered delivery of commuters and goods between locations, transmission and reception of high bandwidth communication as well as surveillance and reconnaissance. The aircraft of the present invention nominally do not consume any hydrocarbon fuel nor do they emit any carbon dioxide. The aircraft of the present invention has the hybrid option of operating with onboard internal combustion engines to back up the electric engines in the event of a cloudy day or additional power requirements.

The present invention further includes solar concentrators which can focus on a power tower equipped with either photovoltaic or turbine based receivers to produce power for the grid or just heating water for process heat during those times when the mirrors are not used to direct solar power to power aircraft.

Historically solar powered airplanes have utilized solar cells, or photo-voltaics, only on the top side of the aircraft wing to power the aircraft during the day. Due to the low intensity of un-concentrated sunlight, these aircraft have been somewhat fragile and slow. The present invention beams sunlight ranging from sun (1,000 Watts/m²) up to concentrations of more than 100 suns (100,000 Watts/m²) onto solar cells on the underside of the aircraft. The solar cells of the present invention operate at efficiencies as high as 44% and generate electricity which powers electric motors and propel the aircraft. Currently the record solar cell is efficiency is 44% and is anticipated to be near 50% by 2020. The use of ground based concentrators plus high efficiency cells enables much higher power and thrust levels and hence higher performance and more robust aircraft than has been the case in the past.

The Solar Relay Aircraft (SRA), in a preferred embodiment, uses an elongated Blended Wing Body (BWB) which is a lifting body aircraft with wings and solar cells on the underside. The elongated/elliptical shape is to allow intercept of reflected sunlight from shallow angles coming from distant mirrors along the path. A blended wing shape exhibits additional benefits including lower drag and higher lift to drag than standard tube and wing aircraft shapes. The aft flow on the bottom of the aircraft serves to cool the solar cells and thereby maintain theft high efficiency. High energy density lithium batteries may provide additional power during takeoff and landing and excursions when there is no solar power available. In an alternative embodiment, the hybrid engine configuration can also be used for takeoff, landings or additional power requirements. An accurate flight path is maintained allowing the use of mirrors with a single axis of rotation. Single axis mirrors will project a straight path of illumination at a given altitude. Modern Differential GPS plus other sensors will comprise an accurate Guidance Navigation and Control (GNC), allowing flight accuracy so that the aircraft stays within the dynamic range of the beam of concentrated sunlight coming from below.

A heliostat, or mirror, facility contains several hundred heliostats. A heliostat (from helios, the Greek word for sun, and stat, as in stationary) is a device that includes a mirror, usually a plane mirror, which turns so as to keep reflecting sunlight toward a predetermined target, compensating for the sun's apparent motions in the sky. The target may be a physical object, distant from the heliostat, or a direction in space. To do this, the reflective surface of the mirror is kept perpendicular to the bisector of the angle between the directions of the sun and the target as seen from the mirror. In almost every case, the target is stationary relative to the heliostat, so the light is reflected in a fixed direction.

In a preferred embodiment, there are nine (9) Heliostat Facilities focusing at one SRA at any point during its flight. These are located 500 meters apart and hence comprise a 4 km span. In one application of the present invention, the SRA flies at 1 km altitude above the Facilities. These 9 facilities form a module. The Concentrator Mirror Array (CMA) is comprised of all the facilities along the route.

In a preferred embodiment, the solar Concentrator Mirror Array (CMA) of the present invention is dual use. The CMA provides intense solar power to the aircraft and also energizes solar Power Towers at each facility to provide power to the grid. Only those mirrors within a several km range will illuminate the aircraft. This is due to the solar divergence angle of ½ a degree. After the aircraft has passed out of range, the initial facilities and mirrors can return their focus to their respective to nearby ground based Power Towers while downrange facilities and mirrors begin to illuminate the aircraft. In this way facilities and mirrors continuously illuminate the underside of the aircraft at typical intensities of 10 to 100 suns during its entire flight. At any time the majority of facilities have the option of also providing grid power. The CMA includes a number of Mirror Modules which are themselves comprised of Mirror Facilities. A Mirror Module is comprised of all those Mirror Facilities which are beaming power to the SRA at a given time. Typically a Mirror Module will include all Mirror Facilities within several km of the SRA as it flies overhead. Each Mirror Facility is a fenced enclosure which contains rows of individual mirrors. Herein, the System is referred to as the totality of SRAs and Power Towers powered by Mirror Facilities.

The CMA is configurable to be used in areas of moderate to high solar insolation, such as between Las Vegas and Los Angeles in the USA or between Alice Springs and Adelaide in Australia. Major benefits include the following: rapid and affordable solar powered aircraft transportation with substantial payloads; little or zero hydrocarbon fuel usage and commensurately near zero carbon dioxide emissions; renewable, zero emission and comparatively affordable grid electric power generated at those same locations.

The present invention includes three primary components, namely the Solar Relay Aircraft (SRA), the Concentrator Mirror Array (CMA) and the Power Towers. There are many advantages to the present invention, including but not limited to:

The SRAs in conjunction with the CMA provides useful transportation with minimal or zero use of hydrocarbon fuels. This reduces the dependence on oil as well as reducing carbon dioxide emissions. In addition since there is minimal to zero exhaust and the expected noise levels to be reduced in comparison with conventional aircraft.

The SRAs are more capable than conventional one-sun powered aircraft due to theft ability to have much higher power densities at the solar cells. This enables heavier payloads and significantly shorter flight times.

The SRA's elongated fuselage BWB elliptically shaped blended wing allows effective intercept of solar rays from the CMA at angles between 10 to 90 degrees from horizontal.

The SRA's high speed air cooled radiator and air flow over the lower surface will circulate water to cool the solar cells and help maintain their efficiency. This is more robust than relying on convective heat transfer to the free stream air boundary layer. It also allows the use of low drag laminar airfoil shapes for the SRA since laminar skin drag is low with laminar heat transfer.

The SRA's blended wing offers a potentially high Lift to Drag ratio of over 20 as compared to conventional airplane shapes having L/Ds between 10 and 20. This reduces power requirements since power is proportional to D/L.

The SRA's electric motor can be over 90% efficient compared to internal combustion engines which are below 40%. The electric motor may also be light weight.

The SRA can be powered with ducted fans or conventional propellers. These typically have efficiencies in excess of 80%.

The SRA's battery can be relatively light weight since it is only used for a few minutes at a time during takeoff and landing.

The SRAs hybrid internal combustion engines/electric engines will allow the SRA to overcome temporary inclement weather and clouds or gaps in the heliostat facilities.

The CMA mirrors/heliostats can be easily maintained with periodic washings.

The CMA mirrors can have only one axis of rotation which reduces cost compared to a heliostats with two axes. Heliostats cost between $100 and $200 per square meter partly due to the second axis. It is expected that the mirrors to cost $100 per square meter or less due to its simple construction. There are also embodiments of the present concept that do have two axes mirrors. Those embodiments can occur where the SRA has a curved flight path say for observation purposes or to navigate a mountain. In that event the mirrors may be more costly per square meter. Alternatively a curved flight path can be accommodated by a discontinuous number of Mirror Facilities along straight paths on the ground. In this case the SRA can rely on battery power for the short amount of time needed to adjust the flight path.

The CMA will deliver concentrated sunlight at a much lower cost than microwaves or lasers. Conventional power beaming using lasers or microwaves is much more expensive than concentrated sunlight especially when the beam forming is included. As long as the SRA has a size commensurate to the reflected solar disc at that range the present invention can be much more cost effective than conventional power beaming. The reflected solar disc diameter is about 1% of the range so for example an SRA diameter of about 1%*1,000 meters=10 meters or more is necessary if the range is 1,000 meters.

The CMA mirrors will deliver concentrated sunlight to a round solar image using inexpensive flat mirror segments. The flat mirrors will be on a structural frame having modest curvature to insure that each flat mirror has the same focus. Alternatively, the curvature of the mirro

The Power Towers have the benefit of using all the surplus solar power to energize the grid. Since the CMA is providing dual use solar photons to the Power Towers, a simple receiver can supply electricity to the grid at affordable cost.

### BRIEF DESCRIPTION OF THE FIGURES

The nature, objects, and advantages of the present invention will become more apparent to those skilled in the art after considering the following detailed description in connection with the accompanying drawings, in which like reference numerals designate like parts throughout, and wherein:

FIG. 1 is a top perspective view of a solar relay aircraft of the present invention;

FIG. 2 is a bottom view of the solar relay aircraft of FIG. 1;

FIG. 3 is a top perspective view of the solar relay aircraft of FIGS. 1 and 2 showing the passenger compartment, battery regulators and battery system;

FIG. 4 is a perspective view of an exemplary mirror facility;

FIG. 5 is a top view of an exemplary mirror facility showing an array of mirrors, and an overhead solar relay aircraft;

FIG. 6 is an exemplary perspective of the solar relay aircraft of the present invention receiving solar power from a number of mirror facilities from directing sunlight towards the aircraft;

FIG. 7 is an exemplary mirror facility equipped with a power tower for receiving solar radiation for conversion to useful energy while not being directed towards a solar relay aircraft;

FIG. 8 is an alternative embodiment of the mirror facility of the present invention;

FIG. 9 is an enlarged view of the solar power tower within a mirror facility to receive the directed solar radiation for conversion to energy, and the associated cooling and inverter systems;

FIG. 10 is an alternative embodiment of the system of the present invention showing a number of mirror facilities, and servicing a variety of solar relay aircraft simultaneously;

FIGS. 11 and 12 are top and bottom perspective views of an alternative solar relay aircraft having an enlarged passenger compartment and an array of electronic equipment for surveillance and monitoring;

FIG. 13 is a top perspective view of the solar relay aircraft of FIGS. 11 and 12;

FIG. 14 is another top perspective view of the solar relay aircraft of FIG. 13 showing the dual propulsion systems;

FIG. 15 is an enlarged view of the dual propulsion systems showing the electric motor and internal combustion engines;

FIGS. 16, 17, and 18 are perspective views of the solar relay mirrors of the present invention, including the heliostat assemblies allowing rotation of elevation and azimuth;

FIGS. 19, 20 and 21 are perspective views of an alternative heliostat providing a radius of curvature adjustment allowing for mirrors having adjustable focal lengths:

FIG. 22 is a block diagram of the system of the mirror facility control;

FIG. 23 is a block diagram of the solar aircraft control system;

FIG. 24 is a system level drawing showing a solar relay aircraft flying over a mirror facility and receiving solar radiation from multiple reflection mirrors;

FIG. 25 is a table of an exemplary commuter aircraft of the present invention;

FIG. 26 is a table of an exemplary mirror facility of the present invention;

FIG. 27 is a table of an exemplary tower cost and performance of the present invention;

FIG. 28 is a table with the economics of the present invention with and without electricity sales; and

FIG. 29 is a graph depicting the nominal sunlight concentration on the solar relay aircraft identifying the “surfing” zone for the solar radiation energy.

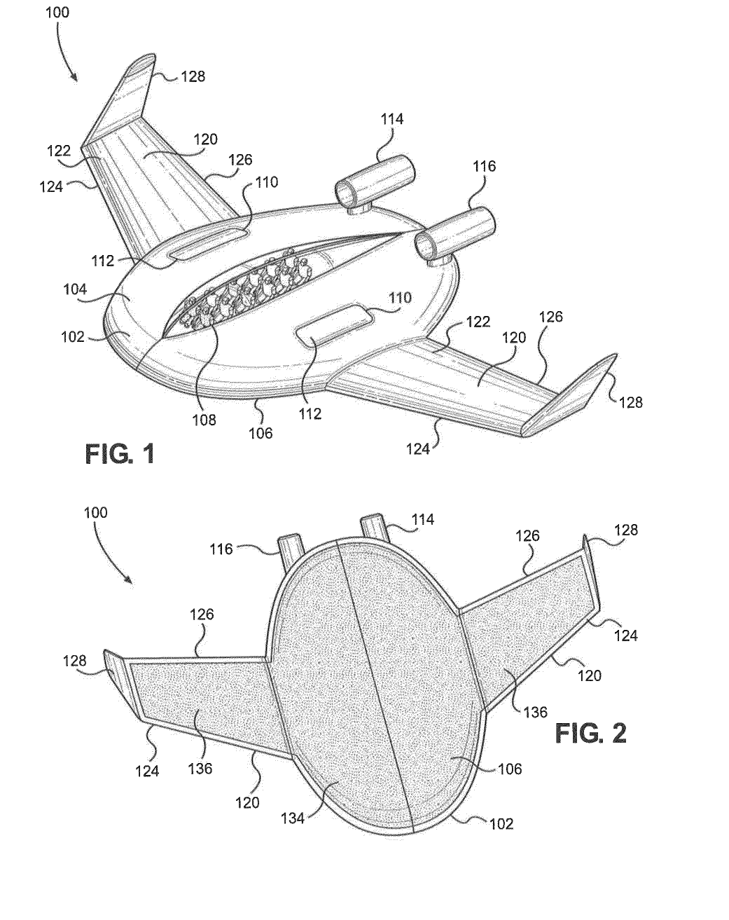

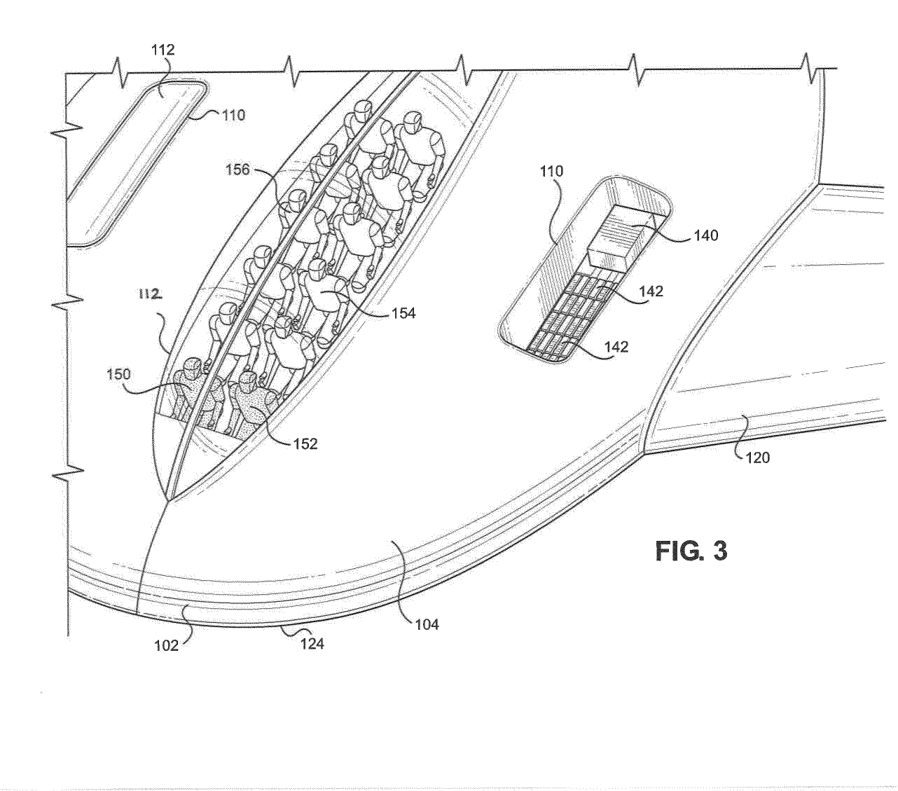

### DESCRIPTION OF INVENTION

The SRA of the present invention weighs 8,000 kg fully loaded and 5,500 kg empty. It has an approximately 100 ft. wingspan and a length of 56 feet. Preliminary fluid dynamic studies indicate the point design cruising at 134 mph (60 m/s) (Table 1). It is expected that additional refinements to yield an aerodynamic shape that will allow cruise at higher speeds. The SRA has power comparable to conventional internal combustion powered aircraft such as the Commuter turboprop EMB 120 Brasilia which seats 30 and weighs 11,500 kg fully loaded. Table 1 shows the SRA performance. The present invention, as a preferred embodiment, includes a 20 passenger aircraft with two pilots for the present example. One goal is to transport passengers and cargo via solar powered airplanes while at the same time producing electricity for the grid. The example flight is between two locations which are 480 km (300 miles) apart. The aircraft can be a propeller driven or ducted fan type with a decent Lift to Drag ratio.

A high performance solar powered aircraft (SRA) is shown and described herein includes an intense concentrated solar beam is reflected from mirrors located along a path on the ground. Unlike conventional solar powered aircraft the SRA has solar cells on the bottom portion of the aircraft instead of the top. (The SRA may also have some solar cells on the top surface but these are much lower power than the cells on the bottom). High Concentration solar cells exist in the industry and run at higher illumination and hence higher current than conventional one sun cells. The SRA has power comparable to conventional internal combustion powered aircraft such as the Cessna Caravan 208 which seats 9 and weighs 4,000 kg fully loaded. Table 1 shows the aircraft performance. Alternatively, a 10 passenger aircraft with two pilots has been considered in conjunction with the present invention. The goal is to transport passengers and cargo via solar powered airplanes while at the same time producing electricity for the grid. The example flight is between two locations which are 320 km (200 miles) apart. The aircraft can be a propeller driven or ducted fan type with a lift to drag ratio between 15 and 25.

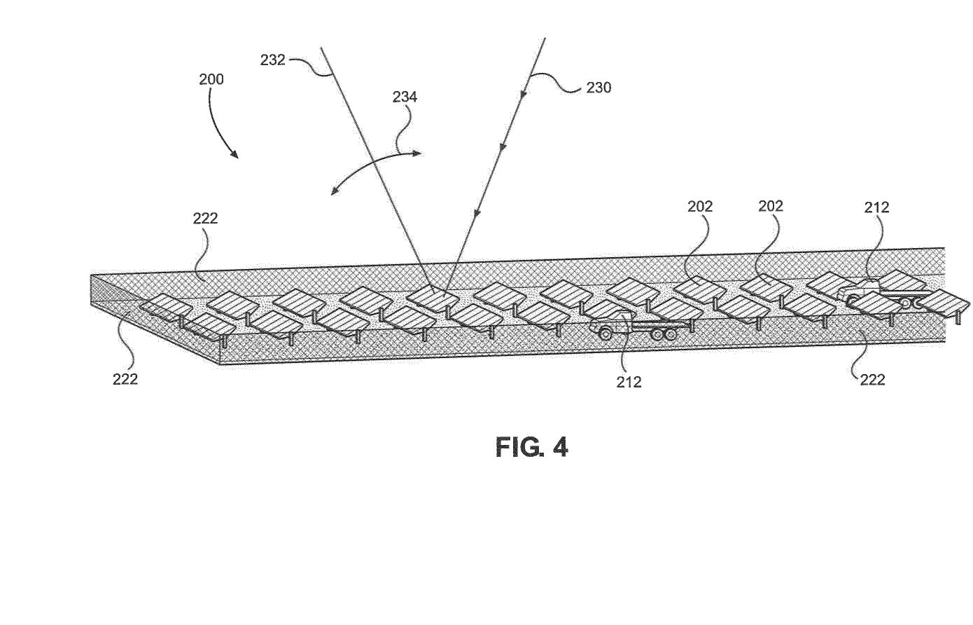

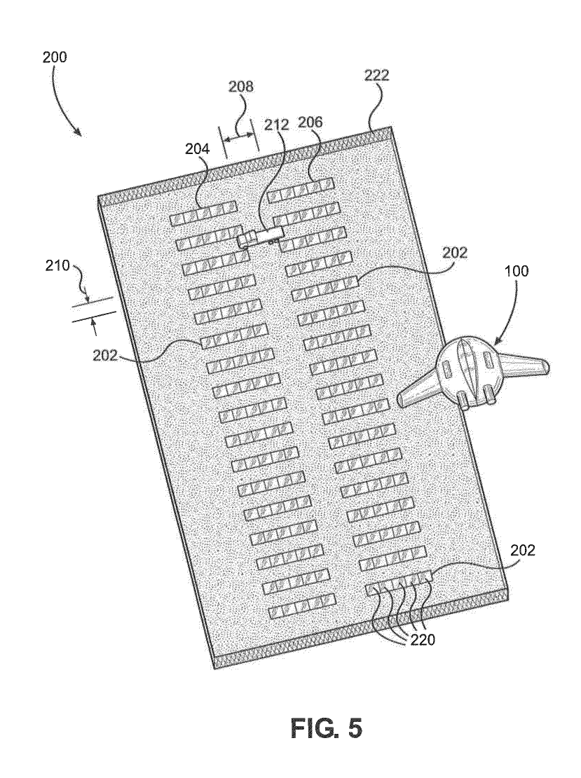

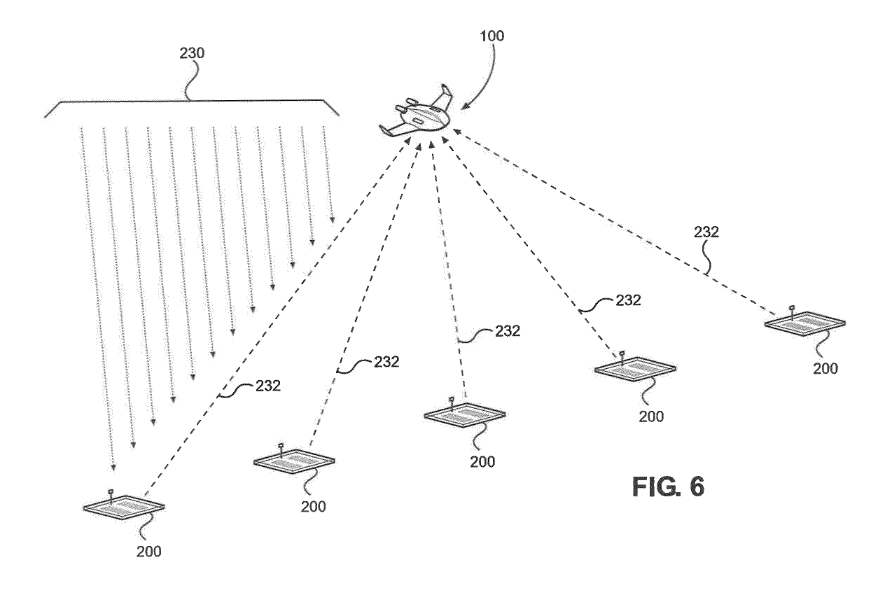

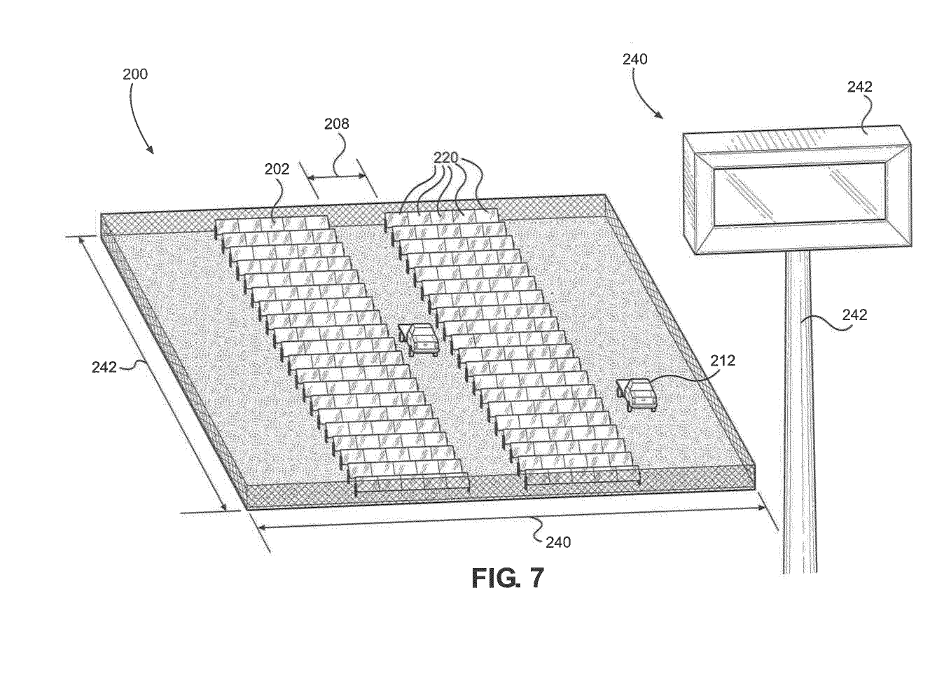

The concentrator solar cells on the underside of the SRA will be Multi-Junction (MJ) have several options. Multiple manufacturers make silicon cells which utilize concentrated sunlight. For example NAREC in Great Britain and Sunpower in the USA make silicon cells have higher efficiencies since they absorb more of the spectrum than other which utilize sunlight up to hundreds of suns (NAREC) or 1-7 suns (Sunpower's Maxeon cells and so they). There are the preferred solution, (FIG. 4) They are successfully used other companies as well that produce cells operating in the Utility PV industry with 10-50 sun range. These silicon cells are typically between 15% and 22% efficient. Conservative estimates that have been used are 22% number for the example aircraft discussed herein. A much higher performance cell is also available called the Multi-Junction Cell (MJ). The MJ uses materials such as germanium, indium, arsenic and gallium to utilize more of the suns spectrum. The world record for solar cells is set with an MJ cell and is over 43% efficient. Companies that manufacture MJ cells include Spectralab, Emcore, Solar Junction and Sharp. The high efficiency MJ cells work best at higher concentrations as high as, typically between 300 and 1,000 suns. Since the CMAs discussed herein provide sunlight at lower concentrations, an MJ coated SRA may require secondary optics to obtain optimum concentration of 17.8 suns as well as requiring close attention to cell cooling. It is expected that the early versions of SRAs will use silicon based cells operating at 15% to 22% due to reduced cell cost. Later versions of SRAs may use MJ cells operating at 30% to 44% if the economics becomes favorable. It is noted that cell efficiency is a major driver for the CMA cost since for example using cells at 44% instead of 22% will reduce the cost of the CMA by a factor of 2. A preferred version assuming cell cost comes down, will use MJ cells at over 30% efficiency. It is preferable to avoid secondary optics on the SRA due to complexity and cost. By avoiding optics the cells may be simply cooled by the air passing over the cell surface. This air cooling will help the cells operate at near nominal efficiency. In those locations with inadequate convective cooling, small heat pipes, turbulators or other means of temperature reduction will be employed. Also note the cells can be protected from the environment by a coating with good mechanical and thermal properties as well as being antireflection and transparent at the wavelengths the cells use.

The SRA shape motivates an elongated disc shaped receiver with the elongation in the direction of the flight path. This matches more of the solar disc when projected on the SRA at an angle at for example 45 degrees from horizontal. An elliptical shape was chosen with 40% elongation for the example SRA in Figures#. This extra length allows the SRA body to intercept sunlight from CMA's at lower angles and hence farther along the flight path, The elongated disc shape is blended into a wing shape as shown. Historically blended wings with this shape have shown_good lift to drag (L/D) ratios around 14 and is expected to do better than this with more aerodynamic refinements and finer meshes in the CFD zoning. The present invention includes a L/D of 15 for example SRA in Table 1. It is likely that a mature SRA will have an L/D between 15 and 20. Tradeoffs between elongation and aerodynamics will be made to optimize the SRA and CMA performance.

The SRA propulsion is based on an electric motors are powered by the concentrator solar cells. In addition there is a lightweight set of Lithium-Ion batteries which provide power for takeoff, maneuvers and landing. Lithium-Ion is the current gold standard for batteries and are used for initial SRAs. Zinc-Air and Lithium-Air batteries are being developed which can potentially have more than 3 times the energy per kg of Lithium-Ion. When they are mature they may be utilized in the SRAs as well. Table 1 identifies the size of the Lithium-ion batteries to provide full power for five minutes. The batteries will start off fully charged and after any usage they will be recharged in flight. The batteries may also be swapped out with fresh batteries after the flight to ensure each flight starts with fully charged batteries. There are several efficiency factors for the SRA:

Concentrator solar cell efficiency is chosen at 42% for the example. This is based on a 44% cell running at 90 Celsius.

Propeller efficiency is chosen at 80% which is conservative
Drive train efficiency includes power conditioning, battery and motor efficiency and is chosen at 80% for the example.
The present invention also includes a power safety factor of 2 to allow the aircraft to fly faster than the nominal 60 to 100 m/s shown in the example as well as accounting for unknown losses.

The SRA has internal combustion engines to augment the electric motors. This hybrid arrangement will allow the aircraft to fly in areas without heliostats or in inclement weather.

The SRA's aerodynamic stability may be enhanced by either mounting the motors near the front of the aircraft or allowing rear mounted motors (as shown) to transmit the axial force to forward locations via rods which are strong in compression. Classic rear engine mounted blended wings have negative longitudinal static margin (around −15%) which implies a fly by wire requirement. It is preferable to maintain a positive margin for the initial SRAs by using the above methods. Later more sophisticated SRAs can be fly by wire.

The SRA's will use real time radar and electro-optic both on board and at the facilities to coordinate the aircraft with the heliostat fields. GPS and differential GPS can also augment the SRA's Guidance Navigation and Control (GN&C). The primary burden is on the heliostat fields to successfully track and illuminate the SRA. In the event of inadequate illumination the SRA has the capability to run on the Internal Combustion Engines until the heliostat fields have reacquired the SRA. The pilot and co-pilot have authority over the autopilot at all times and can be relied on for takeoffs, landings and non-standard conditions.

The SRA's Guidance Navigation and Control (GNC) requirements are fairly precise. It is intended that the SRA to be a “cooperative target” for the mirrors, thereby allowing most of the mirrors to be simply constructed with a single axis of rotation. This means the GNC should maintain the SRA on a trajectory which is precise to within a few meters transverse to the optimum flight path. Accurate GNC will be based on Differential GPS using transmitters at the Mirror Facilities and other locations. Additional GNC sensors can include conventional GPS plus radar, laser rangefinders and Infrared and Optical cameras. An accurate flight path is attainable based on the demonstrated ability of Navy pilots to make accurate carrier landings as well as recent developments in UAVs. The SRA control surfaces will be updated many times per second by the GNC to allow precision flight trajectories. The human pilot will be able to override the GNC if needed. In the event of high winds, storm conditions or lack of adequate sunlight, it is expected to temporarily ground the SRAs.

Differential Global Positioning System” (DGPS) is an enhancement to Global Positioning System that provides improved location accuracy, from the 15 meter nominal GPS accuracy to about 10 cm in case of the best implementations, DGPS uses a network of fixed, ground-based reference stations to broadcast the difference between the positions indicated by the satellite systems and the known fixed positions. These stations broadcast the difference between the measured satellite pseudoranges and actual (internally computed) pseudoranges, and receiver stations may correct their pseudoranges by the same amount. The digital correction signal is typically broadcast locally over ground-based transmitters of shorter range.”

The CMA is comprised of Mirror Modules which are comprised of Heliostat or Mirror Facilities which are in turn comprised of rows of heliostats or mirrors. Each Mirror Module is simply all of those Facilities which are currently illuminating the SRA at any instant. One example of the present invention includes Facilities having 160 Mirror Modules with 9 facilities 5 Mirror Facilities per Mirror Module. Each example Mirror Facility in Table 2 has 180 heliostats or 49 mirrors. Each heliostat, or example mirror, is in a preferred embodiment, 2 meters high by 2 meters long and is comprised of 5 or 10 flat mirrors on a slightly curved structure. Various heliostat configurations may be used and allow more illumination of the SRA due to the geometry.

It is well known that a flat mirror will project a round solar image at ranges beyond several hundred mirror diameters. In addition the size of the solar image will be approximately 1% of the distance. For this reason it is expected that the SRA dimensions to be approximately 1% of the distance to the mirrors. In the present invention, an exemplary SRA altitude of 1 km and hence an SRA receiver transverse, or rough, diameter of 10 meters and a long axis of 14 meters. The analysis shows an optimum height of about 850 m for a 10 meter receiver however the present invention contemplates use of 1 km in an exemplary spreadsheet for simplicity. A 40% elongation of the SRA is chosen to accommodate the projected elongated solar disc coming from more distant mirrors along the path.

The example Heliostats shown in the Figures show a single flat mirror mounted on a slightly curved frame which is then driven by azimuth and elevation gear-motors to comprise a single heliostat or mirror. The curved frame insures that the solar image at the SRA is composed of 5 superposed solar images. The use of flat mirrors will reduce costs. In addition there is the option to coat the mirrors with a material which preferentially absorbs that part of the solar spectrum which is not used by the solar cells. This serves the purpose of reducing the heat load on the underside of the SRA as well as reducing the amount of light reflected by the solar cells.

The heliostat gear-motors are controlled by mirror controller is comprised of a central microprocessor which has an extremely accurate time base. GPS provides a time base that is accurate to the sub microsecond and can be used. A lookup table will be available per each mirror to allow the controller to drive a hydraulic or electrical motor to accurately control the desired mirror angle as a function of time. It is noted that the mirror rotation rate will change during operation and will be faster when the SRA is directly overhead than when the SRA is approaching at a distance.

Basic trigonometry combined with an accurate knowledge of the SRA and sun's location and velocity as well as the sun's precise location. The SRA location and velocity are continually updated via the radar, optics and communication mentioned earlier. Due to temperature changes during the day it is expected that significant changes in the heliostat's aim unless periodic sightings in are performed. Therefore each heliostat will be sighted in one or more times each day by illuminating a target near the Power Tower. This will allow the microprocessor to continually refine and will provide the heliostat's pointing accuracy.

The microprocessor will combine a precise knowledge of the sun's location as well as the SRA parameters to aim each heliostat on a case by case basis, necessary mirror angle. The sun's location is readily calculated as long as accurate time and the facility location are known. The sun's location can also be sensed quite accurately.

One novel feature of the present system is the option to tailor the concentrated sunlight at the SRA such that it peaks near the rear of the SRA. This allows the SRA to get a boost in power if it lags slightly in its flight path. Once the SRA lags, the cells at the rear will get extra sunlight and thereby add more power, providing more thrust and accelerating the aircraft back into the sweet spot. This is referred to as “solar surfing”. An example of nominal solar intensity at the SRA is shown in Graph 1.

Each Heliostat or Mirror Facility is self-contained and has a fence to reduce wind loads and provide security. In the event of high winds the mirrors will rotate to a horizontal low drag configuration. Any dust that accumulates on the mirrors will be removed by periodic washing either by water trucks or automatic sprayers. Additional infrastructure can include gravel or paved roads, a differential GPS station, a weather station, radar, optics and telecommunication to track and direct the SRA, security sensors and alarms, water and sewer plus electrical power and communication. A Heliostat or Mirror Facility Controller will coordinate with the SRA and individual facilities other controllers to direct the mirrors. There can also be housing accommodations for maintenance personnel. The Mirror Facility can operate in conjunction with a nearby Power Tower and they can share the infrastructure as needed.

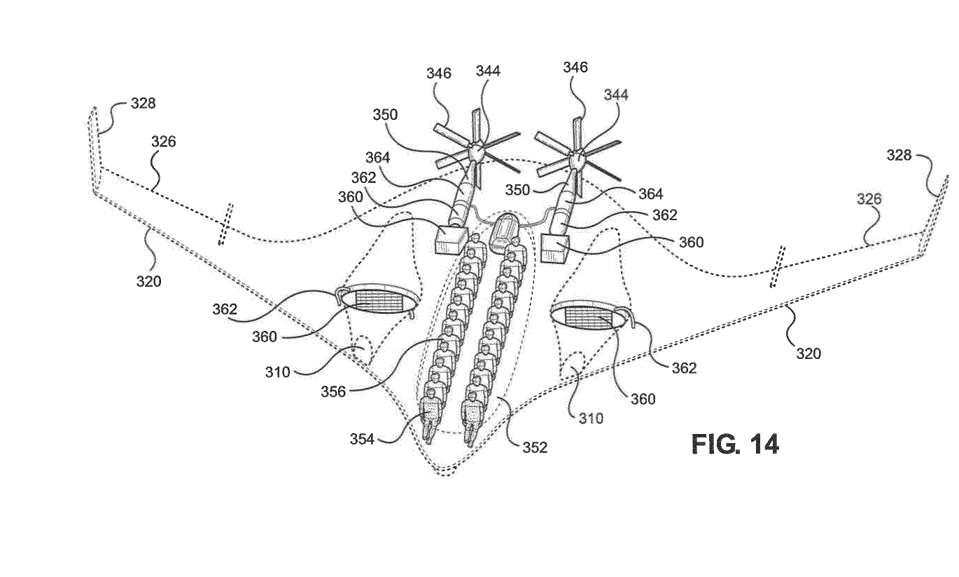

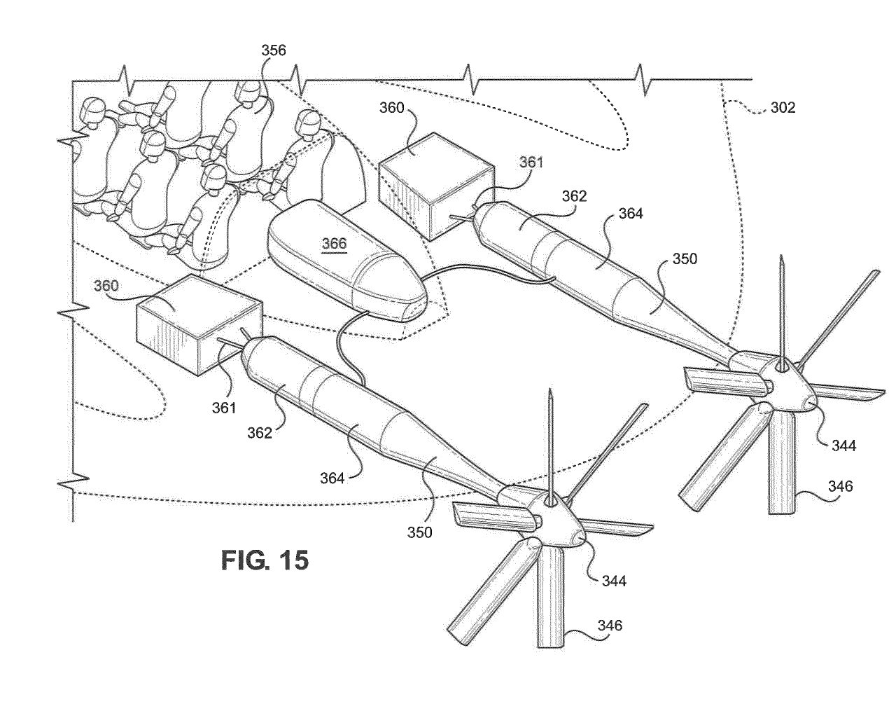

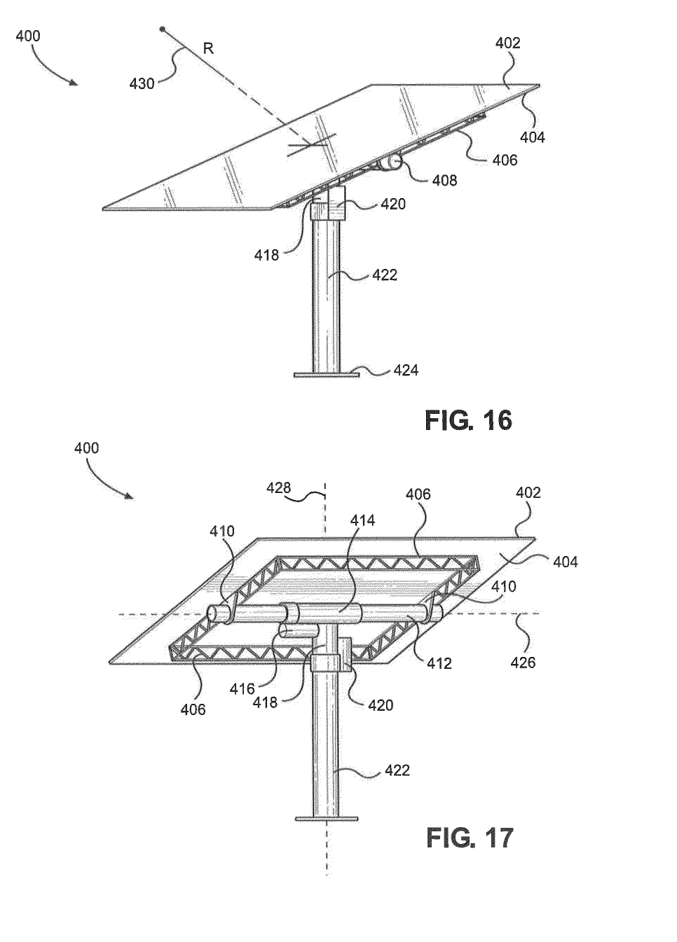

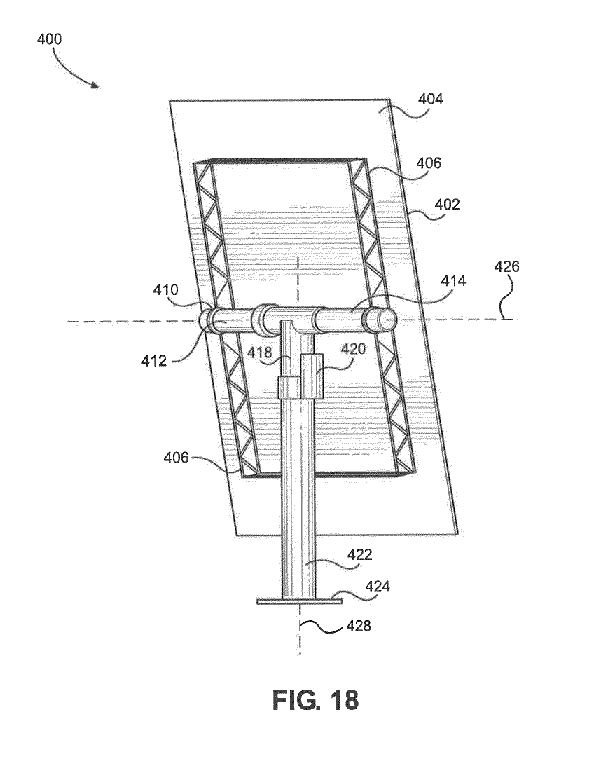

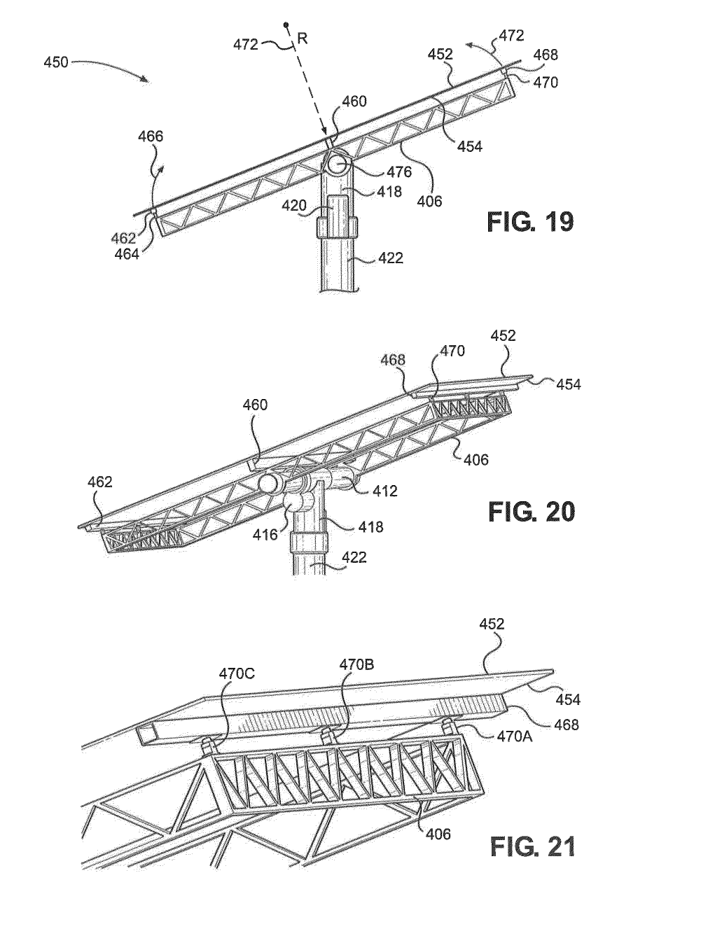

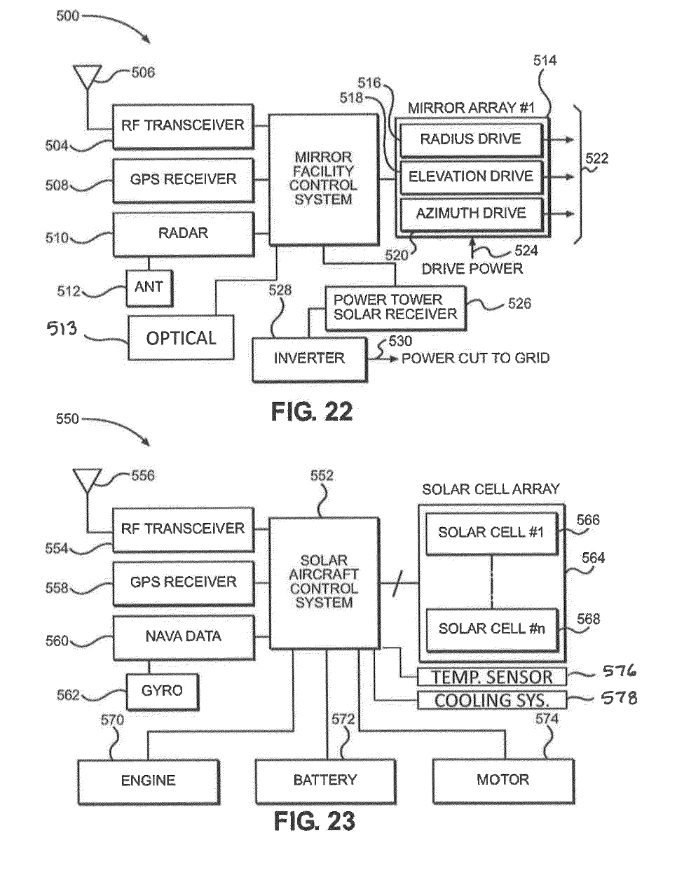

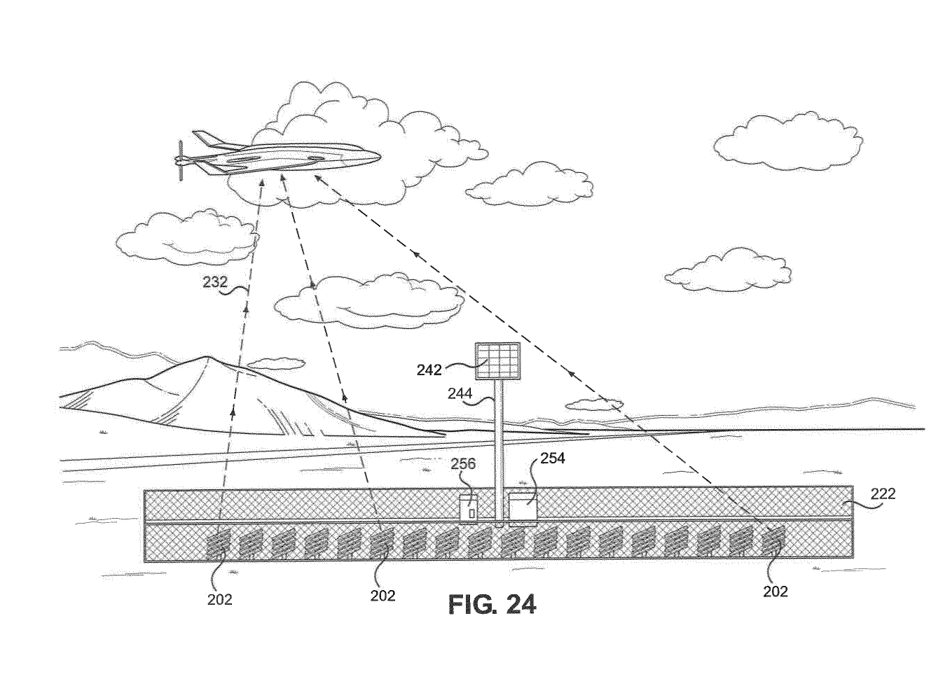

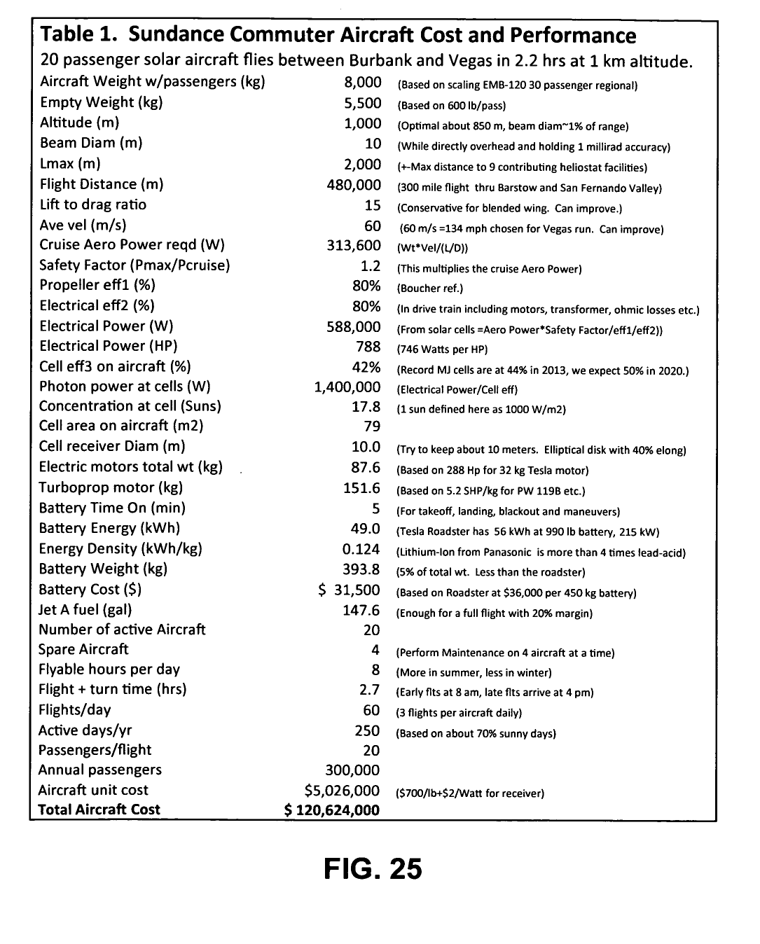

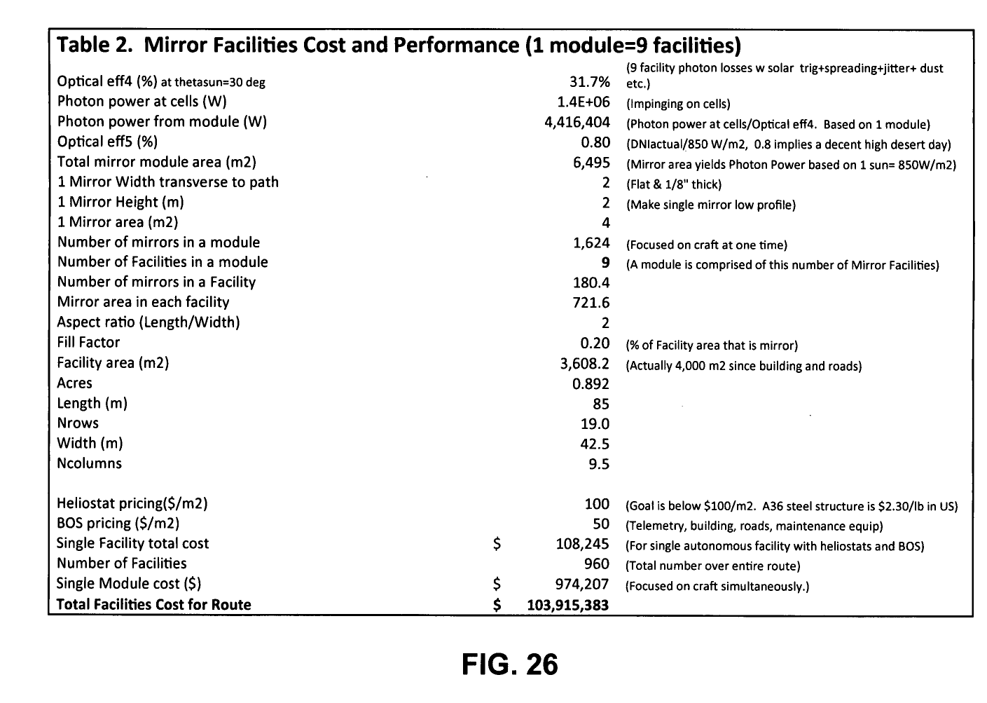

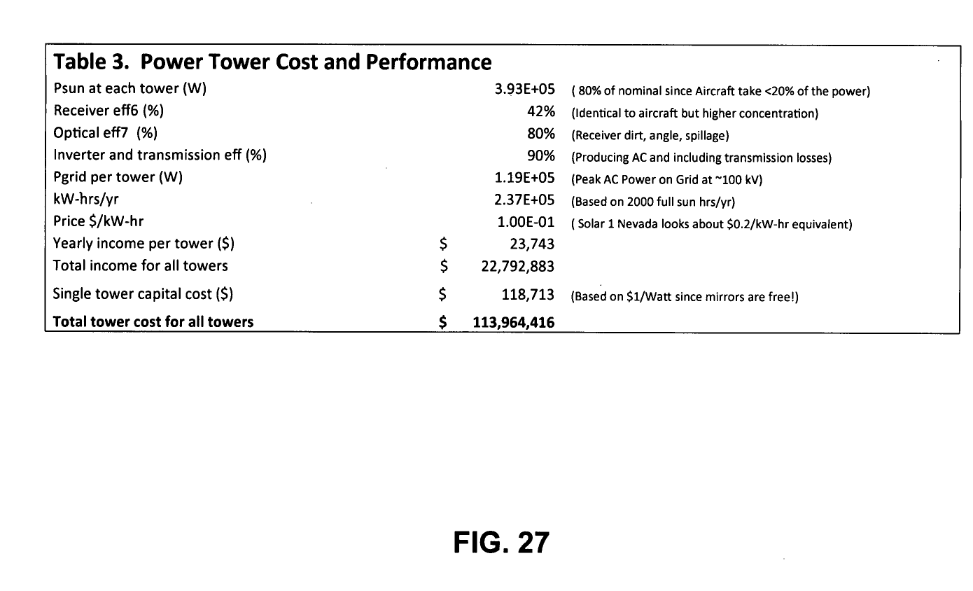

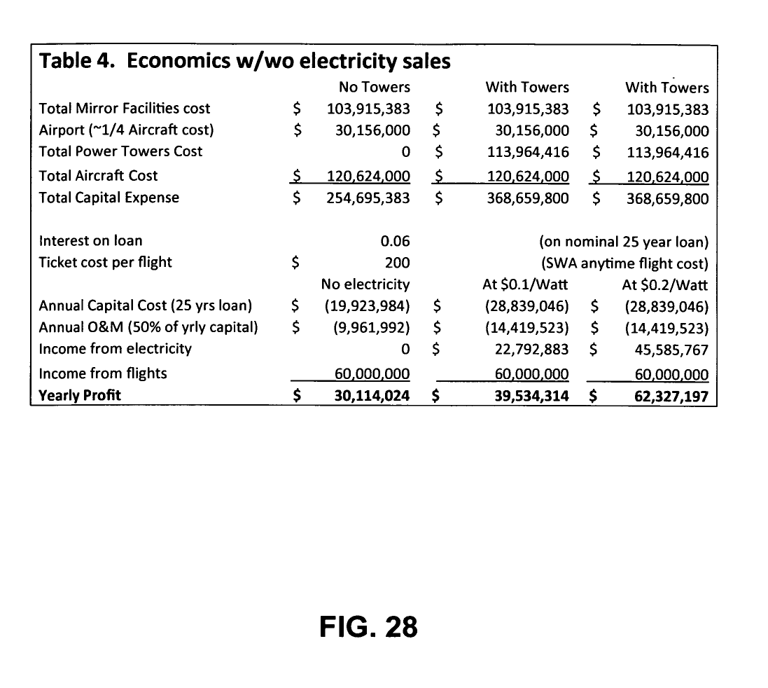

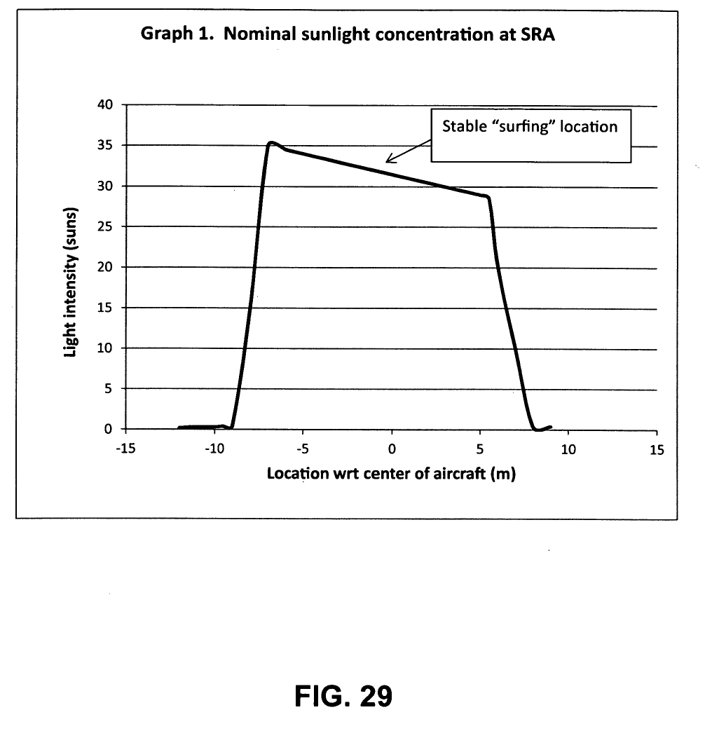

The Power Towers shown in the Figures serve to provide surplus power to the grid when the SRA is not nearby. The Power Towers can be inside the facility and should be low maintenance with some cooling. Mirror Facilities and possibly share a common infrastructure. Since the mirrors don't normally have a transverse rotation axis the Power Tower receiver may require the ability to translate in a direction transverse to the flight path on a daily basis. In addition due to seasonal changes in the sun's apparent trajectory, the Power Tower may require translation during the seasons. Keeping the Power Tower near the Mirror Facility will reduce the height and translation requirements. FIG. 14 shows the typical cooling radiator and power inverter that will accompany each. In the event the Power Tower is tall it may have wheels and be placed on a railroad track transverse to the flight path. Some smaller versions of the Power Towers may be more compact and located very close to the Mirror Facility.

There are two types of Power Tower Receivers which will readily work. The first type is a Rankine Cycle steam turbine. The second type is a photovoltaic receiver made with concentrator solar cells similar to the SRA. The power tower will require not only power generation but also power conditioning including step up transformers.

The economics of the entire SRA, CMA and Power Tower System is described in the FIG. 4 example. The Power Tower option appears favorable for example when power can be sold to the grid at $0.20 per kWh, but may not be favorable if the Power Tower itself is expensive or grid power is cheap. The example shows a yearly profit of $30M, 28M and $40M for the cases of no Power Tower, Power Towers selling electricity at $0.10 per kWh and $0.2 per kWh respectively. In all cases, the SRA ticket sales contribute strongly to the profit.

The UAV reconnaissance version may prove out economically in the event that it is utilized in high DNI locations.

The Broad Band communication relay version may also prove viable as a way to enhance connectivity and augment satellite or radio tower performance,

### Operation of the Present Invention

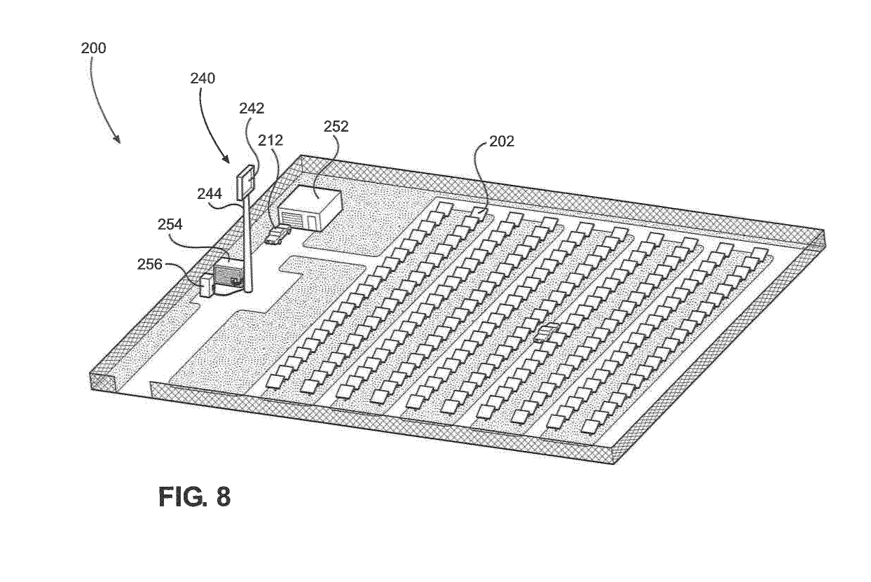

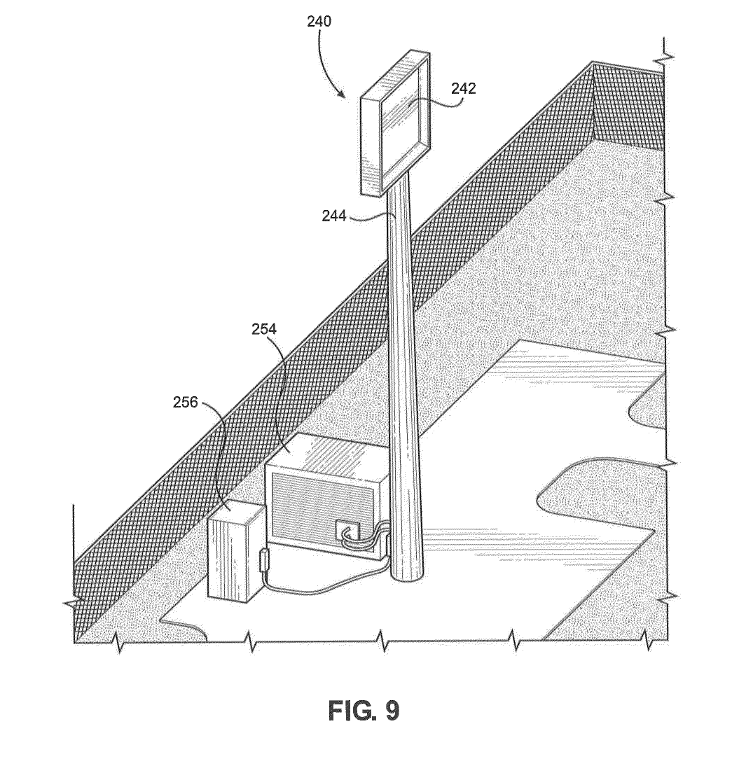

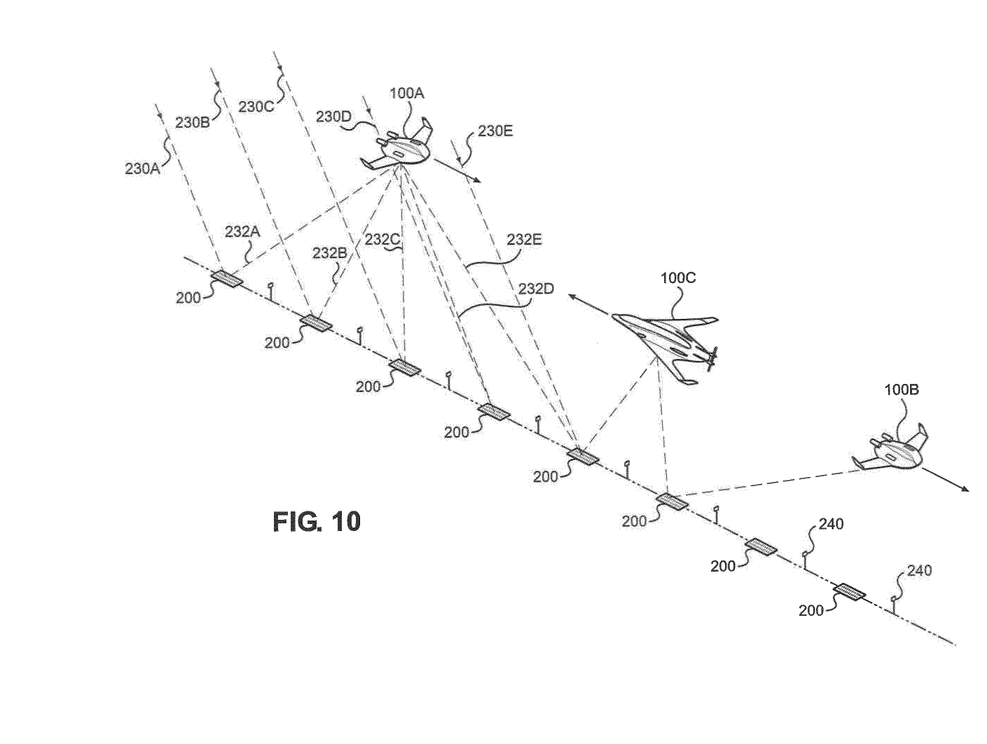

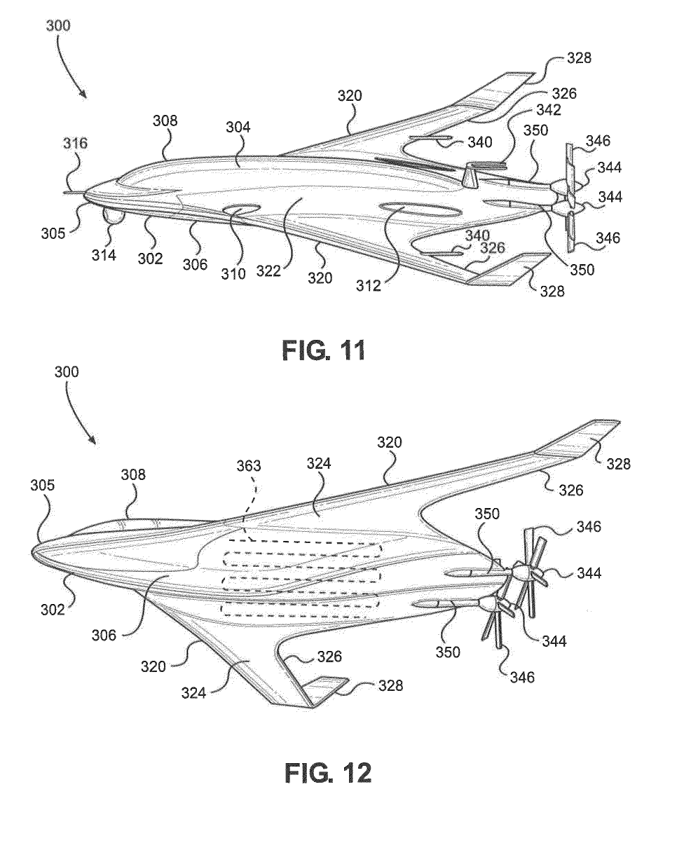

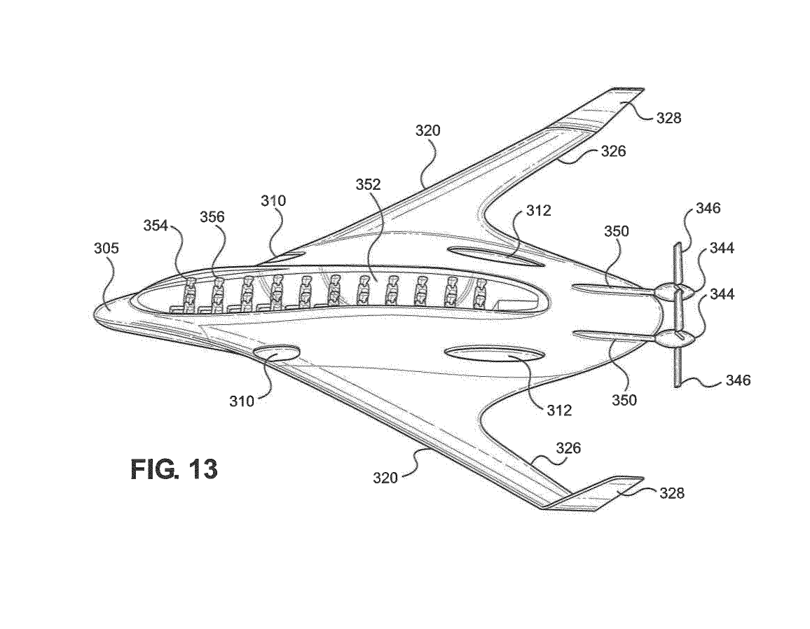

First the weather along the flight path is checked for sunlight, wind etc. If there is adequate sunlight and fair weather and the SRA and CMA are fully operational, the flight is authorized by the flight control tower. Next the SRA takes off from the runway using a fully charged set of batteries. The SRA has the option to run the electric motors or the internal combustion motors at any point in the flight. Once the SRA is high enough, the first mirror facility illuminates the SRA and adds power as the SRA climbs. Meanwhile the Mirror Facility Controllers synchronize the facilities or mirrors and the SRA so that a routine flight may occur. During cruise the SRA autopilot is fully engaged except when the pilot decides to override it. If the SRA encounters large gaps between Mirror Facilities or must change direction it will be powered for a few minutes by the Lithium-Ion Batteries or the internal combustion engines. There may be more than one SRA flying and so the Mirror Facility Controller will intelligently decide which SRAs to illuminate so as not to compromise any SRA performance. In fact outbound and inbound SRAs will pass by each other at different altitudes and it is expected that several hundred meter altitude separation. Based on a 120 m/s closing speed and a 4 km interaction distance there will be about 30 seconds per interaction during which SRAs will experience diminished illumination. This will be compensated for by the battery or the internal combustion engine. As the flight progresses, the batteries will be continuously topped off with excess solar power. The solar cells, electric motors and batteries will be cooled with water from the dual radiators. Ambient “cool” air will enter the inlet diffusers shown in FIGS. 2 and 8. The air will flow through the radiator and heat up and expand prior to leaving through the exit duct. It is likely that some of the heat energy may be converted to thrust to compensate for the increased aircraft drag. This is analogous to the thrust generated by a similar radiator on the WWII P-51 Mustang.

The batteries will also be cooled using ambient air from ducts communicating with the outside air flow. The flight speeds can be several hundred miles per hour and this will make the SRAs competitive with conventional aircraft. In addition the solar cells will be kept near ambient temperature due to the high speed air performing convective cooling. In the event of a serious System malfunction the SRA will be directed to, and land at one of many emergency runways along the flight path.

Meanwhile during the time when no SRAs are being illuminated, surplus solar power will be directed by the mirrors to the Power Towers. The Power Towers will directly provide power to the grid.

When the SRA reaches or approaches its destination the pilot can and it on the runway or let the autopilot perform the landing. From then on the passengers and cargo will disembark as per a conventional aircraft. After the SRA is checked and serviced (including a fresh battery swap) it is ready to provide another flight.

### Alternative Embodiments

The SRA may have any number of shapes with some more efficient at intercepting sunlight and others better aerodynamically. For example a diamond shape or flying wing will also work.

SRAs having the ability to take off and land in water or snow are possible.

The solar cells may use secondary optics on the bottom of the SRA in order to achieve the high concentrations and hence affordability of MJ cells. These optics will likely be Fresnel or Cassegrain.

A propulsion engine based on a heated fluid such as steam is possible. The steam could then power an electric generator or drive a steam engine directly. Steam or another working fluid could also drive a rocket type propulsion engine.

Exotic battery types including Zinc-Air and Lithium-Air are possible. Fuel cells can also work in the event they become affordable.

A small internal combustion engine may help to augment the electric motor in a similar fashion to a hybrid car.

The mirrors may have multiple axes and track the SRAs like searchlights instead of following a set trajectory. Their focus may be dictated all or partially by the aircraft trajectory as it makes turns and accelerates.

A nearly stationary viewing or circling observation platform can be powered by a small number of Mirror Facilities as long as it stays within range.

The Power Towers may be inside the Mirror Facility and may be quite compact thereby reducing capital cost and maintenance.

While there have been shown what are presently considered to be preferred embodiments of the present invention, it will be apparent to those skilled in the art that various changes and modifications can be made herein without departing from the scope and spirit of the invention.

I claim

1. A solar relay aircraft system, comprising:
a solar relay aircraft having an upper surface, and a lower surface;
a solar radiation receiver on said lower surface and capable of converting solar energy to electrical energy;
an electric motor in electrical connection with said solar radiation receiver to receive said electrical energy;
a ground-based reflector array having a plurality of reflecting mirrors for receiving solar radiation from the sun; and
a means for directing said solar radiation from the sun towards said solar relay aircraft.
